(19) United States
(12) Patent Application Publication
(10) Pub. No.: US 2016/0202414 A1
(43) Pub. Date: Jul. 14, 2016

(54) Systems And Methods For Suspended Polymer Photonic Crystal Cavities And Waveguides

(71) Applicant: The Trustees of Columbia University in the City of New York, New York, NY (US)

(72) Inventors: DIRK R. ENGLUND, New York, NY (US); Xuetao Gan, New York, NY (US)

(73) Assignee: The Trustees of Columbia University in the City of New York, New York, NY (US)

(21) Appl. No.: 14/301,216

(22) Filed: Jun. 10, 2014

Related U.S. Application Data
(63) Continuation of application No. PCT/US12/68702, filed on Dec. 10, 2012.
(60) Provisional application No. 61/569,541, filed on Dec. 12, 2011.
(60) Provisional application No. 61/623,996, filed on Apr. 13, 2012.
(60) Provisional application No. 61/667,572, filed on Jul. 3, 2012.

(51) Int. Cl. G02B 6/122; G03F 7/20; H01J 37/317; G01N 21/27; G02B 6/132; G02B 6/138

(52) U.S. Cl. CPC G02B 6/1225; G02B 6/1221; G02B 6/1223; G02B 6/132; G02B 6/138; H01J 37/3174; G01N 21/27; G03F 7/70; G02B 2006/121

(57) ABSTRACT

Systems and methods for suspended polymer photonic crystal (SPPC) cavities and waveguides are disclosed. In one aspect, photonic crystal cavities are provided. An exemplary photonic crystal cavity can include a substrate having a trench. A polymer film can be suspended above the trench thereby forming a gap between the polymer film and the substrate. The polymer film can include a plurality of holes to thereby form at least one optical cavity. The plurality of holes can have a lattice spacing, and each hole can have a radius. The radius and lattice spacing of the plurality of holes can be adapted to increase a gap-midgap ratio. In another aspect, photonic waveguides are provided. In another, methods for fabricating an SPPC are provided. In another, methods for sensing using a polymer photonic crystal ladder cavity are disclosed. In another, methods for optical filtering using an SPPC waveguide-coupled cavity drop filter are disclosed.

### CROSS REFERENCE TO RELATED APPLICATION

This application claims priority from PCT/US12/68702 filed Dec. 10, 2012, U.S. Provisional Application Ser. No. 61/667,572, filed Jul. 3, 2012, U.S. Provisional Application Ser. No. 61/623,996, filed Apr. 13, 2012, and U.S. Provisional Application Ser. No. 61/569,541, filed Dec. 12, 2011, which are incorporated by reference herein.

### STATEMENT REGARDING FEDERALLY SPONSORED RESEARCH OR DEVELOPMENT

This invention was made with government support under grant No. DE-AC02-98CH10886, awarded by the Department of Energy, Office of Basic Energy Sciences. The government has certain rights in the invention.

### BACKGROUND

The disclosed subject matter relates to techniques for suspended polymer photonic crystal cavities and waveguides.

Photonic crystal cavities and waveguides can be used in photonic integrated chips (PICs), which can provide compact, efficient architectures for classical and quantum information processing systems. Photonic crystal cavities and waveguides can also have applications in the telecommunication industry, in quantum photonics, in biophotonics, in non-linear photonics, as sensors, as active components in optical systems, and as classical and non-classical light sources, among other things.

Polymers can be used to make optical cavities and waveguides, and can provide relative flexibility, tunable chemical and physical properties, and ease of assembly compared to certain other optical materials. However, the low refractive index contrast between the polymer light guiding layer and a substrate can hinder the implementation of polymer photonic crystals. There is a need for an architecture that enables a higher refractive index contrast and allows for a photonic band-gap in polymer photonic crystals.

### SUMMARY

Systems and methods for suspended polymer photonic crystal cavities and waveguides are disclosed herein.

In one aspect of the disclosed subject matter, photonic crystal cavities are provided. An exemplary photonic crystal cavity can include a substrate having a trench on at least one surface. A polymer film can be suspended above the trench, forming an air gap between at least a portion of the polymer film and the substrate. The suspended polymer film can include a periodic plurality of air holes The holes can have a lattice spacing, and each of the plurality of holes can have a radius. The radius and the lattice spacing of the plurality of holes can be adapted to increase a photonic band gap-midgap ratio.

In some embodiments, the polymer film can have a periodic two-dimensional hexagonal array of holes having one or more defects. The photonic crystal cavities can be defined by the defects. In some such embodiments, the radius of the holes can be three-tenths of the lattice spacing, and the polymer film can have a thickness of 1.3 times the lattice spacing. In other embodiments, the radius can be 0.36 times the lattice spacing, and the polymer film can have a thickness 1.5 times the lattice spacing.

In some embodiments, the defect can be three missing holes in a linear arrangement. Thus, the defect can have a width of one hole and a length of three holes in the array of holes. In some such embodiments, the radius and lattice spacing of the six holes adjacent to the defect can be adapted to attenuate a vertical radiation loss. In some embodiments, the defect can further include additional holes. The shape, spacing, and radius of the additional holes can be adapted to enhance a Q-factor. In some such embodiments, the additional holes can be a linear arrangement of three holes, including a first end hole, a middle hole, and a second end hole.

In some embodiments, polymer film can have a periodic one-dimensional array of rectangular holes. In such embodiments, the optical cavity can be a ladder cavity.

In some embodiments, the polymer film can be 400 nm thick poly(methyl methacrylate) (PMMA), which is 0.9 times the lattice spacing of the rectangular holes.

In another aspect of the disclosed subject matter, photonic waveguides are provided. An exemplary photonic crystal waveguide can include a substrate having a trench on at least one surface. A polymer film can be suspended above the trench. The polymer film can have a mesh of supporting elements therein. The polymer film can have a plurality of channels, such that only the mesh remains in the channels, thereby providing a photonic crystal suspended above the trench by at least one of the supporting elements.

In some embodiments, the mesh of supporting elements can be a mesh of carbon nanotubes.

In some embodiments, the photonic crystal waveguide can be a ladder cavity. In some embodiments, the polymer film can be 400 nm thick PMMA.

In another aspect of the disclosed subject matter, methods for fabricating a suspended polymer photonic crystal are provided. An exemplary method can include depositing a polymer film onto a polymer substrate. One or more photonic crystals can be patterned into the polymer film. At least a portion of the polymer substrate can be removed from a region proximate to the photonic crystal. The polymer film can then be transferred onto a carrier substrate. In some embodiments, the carrier substrate can have a trench.

In some embodiments, the polymer substrate can comprise a layer of polyvinyl alcohol (PVA). The PVA layer can be removed by dissolving the PVA layer in water.

In some embodiments, the photonic crystal can be patterned in the polymer film by one of electron beam lithography, optical beam lithography, and nanoprinting.

In some embodiments, the polymer film can have a mesh of supporting elements therein, and the photonic crystal can be patterned in the polymer film by exposing channels that surround the at least one photonic crystal so that only the mesh remains in the channels.

In another aspect of the disclosed subject matter, methods for sensing using a polymer photonic crystal ladder cavity suspended in air and having a resonant wavelength are disclosed. An exemplary method can include applying a stretching force to the ladder cavity that causes a displacement. The shift in the resonant wavelength due to the displacement can be measured.

In some embodiments, the displacement can be calculated based on the shift in resonant wavelength.

In some embodiments, the stretching force can be calculated based on the shift in resonant wavelength.

In some embodiments, the ladder cavity can be used for biochemical sensing. In such embodiments, the stretching force can be applied to the ladder cavity by (1) incorporating biochemical compounds into the ladder cavity and (2) soaking the ladder cavity in a solution thereby causing the biochemical compounds to expand.

In another aspect of the disclosed subject matter, methods for optical filtering using a suspended polymer photonic crystal waveguide-coupled cavity drop filter are disclosed. An input waveguide can be pumped with a broadband electromagnetic radiation source. A photonic crystal cavity can be coupled to the input waveguide such that there is a resonant mode between the input waveguide and the photonic crystal cavity. A drop waveguide can be coupled to the photonic crystal cavity, thereby transmitting the resonant mode to the drop waveguide. In some embodiments, the refractive index of the photonic crystal cavity can be adjusted, thus adjusting the resonant mode.

### BRIEF DESCRIPTION OF THE DRAWINGS

FIG. 1 shows an exemplary L3 photonic crystal cavity in a two-dimensional hexagonal lattice according to some embodiments of the disclosed subject matter.

FIG. 2 shows an exemplary photonic crystal waveguide supported by a mesh of supporting elements according to some embodiments of the disclosed subject matter.

FIG. 3 shows an exemplary photonic crystal ladder cavity according to some embodiments of the disclosed subject matter.

FIG. 4 shows an exemplary photonic crystal ladder cavity supported by a mesh of supporting elements according to some embodiments of the disclosed subject matter.

FIG. 5 shows an exemplary one-dimensional photonic crystal cavity in a ladder cavity according to some embodiments the disclosed subject matter.

FIG. 6 shows an exemplary one-dimensional photonic crystal cavity in a ladder cavity supported by a mesh of supporting elements according to some embodiments of the disclosed subject matter.

FIG. 7 shows the energy field distribution of simulated resonant modes in a ladder cavity according to some embodiments of the disclosed subject matter.

FIGS. 8A-D show experimental characterizations of two-dimensional photonic crystal cavities and waveguides according to some embodiments of the disclosed subject matter.

FIGS. 9A-D show images of the implementation of a one-dimensional ladder cavity-based stretch sensor according to some embodiments of the disclosed subject matter.

FIGS. 10A-F show images of various suspended polymer photonic crystal (SPPC) devices according to some embodiments of the disclosed subject matter.

FIGS. 11A-C show simulations of hexagonal lattice SPPC devices according to some embodiments of the disclosed subject matter.

FIGS. 12A-C show experimental characterization results of the PBG of certain SPPC devices, the resonance of an L3 cavity, and the transmission of a bend waveguide according to some embodiments of the disclosed subject matter.

FIGS. 13A-C show a demonstration of an SPPC waveguide-coupled cavity drop filter according to some embodiments of the disclosed subject matter.

FIGS. 14A-B show the energy density distribution of an L3 cavity and an M3 cavity according to some embodiments of the disclosed subject matter.

FIG. 15 shows the spatial Fourier Transform (FT) of the confined electric field for a resonant mode at the frequency of 0.5217 for a polymer photonic crystal L3 cavity according to some embodiments of the disclosed subject matter.

FIGS. 16A-B show the comparison between elliptical photonic crystal PBG and related circular photonic crystal PBG (FIG. 16A) and PBG improvement of an elliptical photonic crystal (FIG. 16B) according to some embodiments of the disclosed subject matter.

FIG. 17 shows an exemplary process for sensing using a photonic crystal ladder cavity according to some embodiments of the disclosed subject matter.

FIG. 18 shows an exemplary process for optical filtering using an SPPC waveguide-coupled cavity drop filter according to some embodiments of the disclosed subject matter.

FIG. 19 shows an exemplary process for fabricating SPPC devices according to some embodiments of the disclosed subject matter.

Throughout the drawings, similar reference numerals and characters, unless otherwise stated, are used to denote like features, elements, components or portions of the illustrated embodiments. Moreover, while the disclosed subject matter will now be described in detail with reference to the FIGS., it is done so in connection with the illustrative embodiments.

### DETAILED DESCRIPTION

The disclosed subject matter provides systems of suspended polymer photonic crystal (SPPC) cavities and waveguides as well as methods to make and use SPPC cavities and waveguides.

For purpose of illustration and not limitation, exemplary embodiments of the disclosed subject matter will be described with reference to the figures. In certain exemplary systems, polymer photonic crystals (PCs) can be clad in, or surrounded by, air. Certain substrates can have a similar refractive index to polymer photonic crystals, which can negatively impact the performance of a photonic crystal (PC) cavity or waveguide. Having a greater contrast in refractive index can provide for greater internal reflection, which results in less loss in the photonic crystal cavity or waveguide. There can be a greater refractive index contrast between polymer and air than between polymer and substrate. By suspending the polymer photonic crystals above a trench in a substrate, the polymer photonic crystals can contact air instead of being in contact with the substrate, which results in greater refractive index contrast at the boundaries of the photonic crystal. Furthermore, the geometry of the systems can be adjusted to enhance performance. For purposes of illustration and not limitation, exemplary methods of fabricating and using SPPC systems are also disclosed.

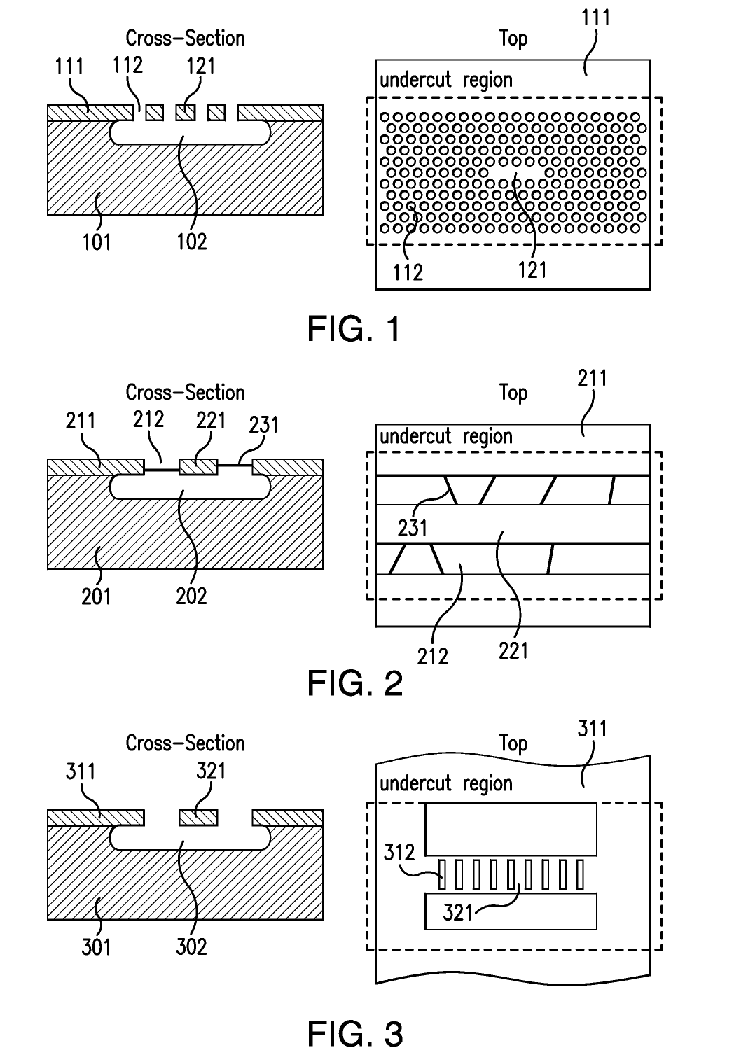

Referring to FIG. 1, an exemplary SPPC cavity is disclosed. A substrate 101 can be provided. By way of example and not limitation, the substrate 101 can be a 10 nm thick layer of polyvinyl alcohol (PVA). The PVA layer can be on top of a bare silicon wafer (not pictured). By way of example and not limitation, the substrate 101 can be a glass substrate. A polymer film 111 can be deposited on top of the substrate 101. By way of example and not limitation, the polymer film 111 can be 390-400 nm thick poly(methyl methacrylate) (PMMA) film, or other polymer film preferably with refractive index of at least 1.5, that is spin-coated onto the substrate 101. The film 111 can be doped with organic dye or quantum dots to act as a light source and simplify characterizations of the SPPC devices. By way of example and not limitation, the organic dye can be Coumarin 6 by weight of 2%. The dye can be pumped by a continuous wave laser. By way of example and not limitation, the dye can be pumped by a continuous wave 405 nm laser to achieve a peak photoluminescence (PL) of 530 nm.

A lattice of holes 112 can be formed in the polymer film 111. As used herein, a lattice can be any regular geometrical arrangement of holes. By way of example and not limitation, the holes 112 can be in a two-dimensional (2D) hexagonal array. By way of example and not limitation, the holes 112 can have a radius between 0.3 and 0.37 times the lattice spacing and the polymer film 111 can have a thickness of 1.3-1.5 times the lattice spacing. By way of example and not limitation, the lattice spacing can be 300 nm and the radius of the holes 112 can be between 90 and 108 nm. A photonic crystal cavity 121 can be formed by a defect in the lattice. By way of example and not limitation, the photonic crystal cavity can be an L3 cavity. As used herein, an L3 cavity refers to a cavity defined by a defect that is the size of three linearly aligned missing holes in the lattice.

At least a portion of the substrate 101 can be removed from below the photonic crystal cavity 121 so that a trench 102 can be formed. As used herein, trench refers to any undercut, hole, gap, etc. in the substrate 101. By way of example and not limitation, the trench 102 can be formed by a chemical etch, e.g., a hydrofluoric acid etch to remove at least a portion of a glass or silicon dioxide substrate 101. By way of example and not limitation, the trench 102 can be formed by dissolving at least a portion of a PVA substrate 101. Thus, the photonic crystal cavity 121 can be suspended above the trench 102 so that there is a gap between the photonic crystal cavity 121 and the substrate 101. In this way, the photonic crystal cavity 121 does not contact the substrate 101 and is instead clad in, or surrounded by, air.

By way of example and not limitation, the patterned polymer film 111 can be separated from the PVA substrate 101 by dissolving the PVA layer in water. The patterned polymer film 111 can be transferred onto a carrier substrate (not pictured). The carrier substrate can have a trench. The polymer photonic crystals 121 can be transferred on top of the trench to form suspended polymer photonic crystals. By way of example and not limitation, the carrier substrate can be a photoresist, which can be etched by the developer.

By way of example and not limitation, the dimensions of the holes 112, the cavity 121, the film 111, and the trench 102 can be chosen based on three-dimensional (3D) finite-difference time-domain (FDTD) simulations. For example, the MIT Photonic-Bands (MPB) package, which is free software developed by MIT, can be used to compute band structures (dispersion-relations) and electromagnetic modes of periodic dielectric structures. MEEP, which is free FDTD software developed by MIT, can be used to model electromagnetic systems.

As used herein, the band above a photonic band gap (PBG) can be defined as the air band, and the band below a PBG can be defined as the dielectric band. As used herein, ωₘ can be the frequency at the middle of the PBG and δω can be the frequency width between the air band and the dielectric band. The gap-midgap ratio can be defined as δω/ωₘ. The size of the PBG can be characterized by the gap-midgap ratio. The total Q-factor (Qₜₒₜ) of a 2D photonic crystal cavity 121 can be divided into two parts, in-plane (Q_{∥}) and vertical (Qᵥ), which can have the relationship

1/Qₜₒₜ=(1/Q_{∥})+(1/Qᵥ). (1)

In a 2D photonic crystal cavity 121, light can be confined within the defect region by two mechanisms: in-plane by distributed Bragg reflection (DBR) and vertically by total internal reflection (TIR). The in-plane confinement can be determined by the number of periods of the lattice (i.e. number of holes 112) surrounding the cavity, and the resonant frequency of the defect mode can lie within the in-plane guided mode PBG. Thus, more periods surrounding the cavity 121 can lead to stronger in-plane confinement and greater in-plane Q-factor (Q_{∥}H). Vertical confinement can be due to standard waveguiding by TIR. By way of example and not limitation, the entire structure (photonic crystal cavity and surrounding lattice) can be 28a×24a×8a where a is the lattice spacing. By way of example and not limitation, the grid size can be 0.05a in the x, y, and z directions, and perfect matched layers can be used as absorbing boundaries. The modal volume V can be calculated by

$$V = \frac{\int \int \int ∈ {( x , y , z )}^{*} {\vert E ( x , y , z ) \vert}^{2} d x d y d z}{max [ ∈ {( x , y , z )}^{*} {\vert E ( x , y , z ) \vert}^{2} ]} , \qquad ( 2 )$$

where ε(x,y,z) is the dielectric function in the simulation structure, max[ε(x,y,z)] is the dielectric constant at the position with the maximum electric field, and

|E(x,y,z)|²=|Eₓ(x,y,z)|²+E_{y}(x,y,z)|²+|E_{z}(x,y,z)|². (3)

By way of example and not limitation, the lattice can be simulated without any defects in order to estimate appropriate dimensions for the lattice spacing and radius of the holes 112. For example, a PMMA film 111 with a refractive index of 1.52 and infinite thickness and holes 112 with lattice spacing a can be simulated to estimate what radius of the holes 112 can enhance the PBG. PMMA film cannot have infinite thickness in reality, but it can be useful in an initial set of simulations to model it as such. Although the index contrast between PMMA and air is only 1.52, significant photon bandgaps (PBGs) can be achieved in polymer photonic crystals. By way of example and not limitation, the radius can be 0.37a. Then a PMMA film with thickness limited to no larger than 1.5a (to avoid multiple mode propagation) can be simulated with holes 112 of radii around 0.37a to estimate what dimensions enhance the gap-midgap ratio. By way of example and not limitation, the thickness of the film 111 can be 1.5a and the radius of the holes 112 can be 0.36a.

By way of example and not limitation, a photonic crystal cavity 121 can then be simulated in a film 111 with holes 112 having dimensions around those dimensions discussed above. Vertical confinement in the cavity 121 can be due to standard wave guiding by TIR. In momentum space analysis, vertical radiation losses of the cavity can occur when the cavity modes have in-plane momentum components that lie within a region called the light cone. A larger fraction of in-plane momentum components that lie in the light cone can lead to larger vertical radiation loss and a smaller Q-factor for the cavity. By way of example and not limitation, if the cavity 121 is an L3 cavity, the spacing and radii of the six air holes near the L3 cavity edges (i.e. adjacent to the cavity 121) can be fine-tuned to reduce vertical radiation loss.

By way of example and not limitation, the Q-factor of a polymer L3 cavity clad in air can be over 2,000 and as high as 3,000 at a frequency of 0.491(2πc/a) where c is the speed of light in a vacuum and a is the lattice spacing. These values are surprisingly high for a polymer photonic crystal cavity. By way of example and not limitation, mode volumes on the order of the cube of the wavelength can be obtained in a polymer L3 cavity clad in air. For example, mode volumes V can be below 1.7(λ/n)³ and as low as 1.68(λ/n)³, where λ is the wavelength and n is the refractive index. By way of example and not limitation, the Q-factor/mode volume (Q/V) ratio can be over 1,000(λ/n)⁻³ in a polymer L3 cavity clad in air. By way of example and not limitation, yields as high as 98% can be achieved in a polymer L3 cavity clad in air based on experimental implementations.

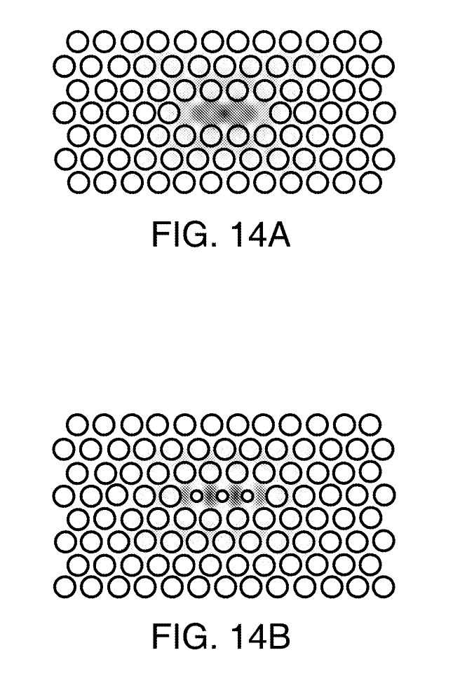

By way of example and not limitation, additional holes can be located within the photonic crystal cavity 121. As used herein, an M3 cavity is a photonic crystal cavity 121 where three additional linearly aligned holes are located within an L3 cavity. M3 cavities are discussed in connection with FIG. 14 below.

Referring to FIG. 2, an exemplary SPPC waveguide is disclosed. A substrate 201 can be provided. A polymer film 211 can be deposited on top of the substrate 201. The polymer film 211 can have a mesh of supporting elements 231 therein. At least two channels 212 can be formed in the polymer film 211 wherein the polymer film is removed so that only the mesh remains in the channels. By way of example and not limitation, the channels 212 can be two parallel linear channels. A photonic waveguide 221 can be formed between two channels 212. By way of example and not limitation, the photonic waveguide 221 can be a linear waveguide. At least a portion of the substrate 201 can be removed from below the photonic waveguide 221 so that a trench 202 can be formed. By way of example and not limitation, the trench 202 can be formed by any of the methods discussed above. Thus, the photonic waveguide 221 can be suspended above the trench 202 by the supporting elements 231 so that there is a gap between the photonic crystal cavity 221 and the substrate 201. By way of example and not limitation, the supporting elements 231 can be a mesh of carbon nanotubes. The supporting elements 231 can be made of any material that does not interfere with the operation of the cavity. Preferably, the supporting elements 231 should not overlap with the cavity resonance because such overlap can lead to photon scattering or photon absorption. In this way, the photonic waveguide 221 does not contact the substrate 201 and is instead clad in, or surrounded by, air.

Referring to FIG. 3, an exemplary SPPC ladder cavity is disclosed. A substrate 301 can be provided. A polymer film 311 can be deposited on top of the substrate 301. A lattice of holes 312 can be formed in the polymer film 311. By way of example and not limitation, the holes 312 can be in a one-dimensional (1D) array of rectangular holes. By way of example and not limitation, the holes 312 can also be elliptical. Thus, a ladder cavity 321 can be formed by the lattice. By way of example and not limitation, the holes 312 can be equidistantly spaced. By way of example and not limitation, the holes can have an initial lattice spacing a at one end of the ladder cavity, and the lattice spacing can gradually or parabolically be decreased over several periods (e.g. 5 periods) to a smaller lattice spacing (e.g. 0.9a) at the center of the ladder cavity, and then the lattice spacing can be gradually or parabolically increased over several periods back up to the initial lattice spacing a at the other end of the ladder cavity. At least a portion of the substrate 301 can be removed from below the ladder cavity 321 so that a trench 302 can be formed. By way of example and not limitation, the trench 302 can be formed by any of the methods discussed above. Thus, the ladder cavity 321 can be suspended above the trench 302 so that there is an air gap between the ladder cavity 321 and the substrate 301. In this way, the ladder cavity 321 does not contact the substrate 301 and is instead clad in, or surrounded by, air. By way of example and not limitation, the ladder cavity 321 can be 700 nm wide and 10 μm high. By way of example and not limitation, the thickness of the film 311 can be 0.9 times the lattice spacing, the beam width of electromagnetic radiation entering the ladder cavity 321 can be 3 times the lattice spacing, the width of the holes 312 can be half of the lattice spacing, and the height of the holes can be 0.7 times of the beam width.

By way of example and not limitation, the Q-factor of a polymer ladder cavity clad in air can be over 12,000 and as high as 107,500. By way of example and not limitation, mode volumes on the order of the cube of the wavelength can be obtained in a polymer ladder cavity clad in air, which can be below 1.4(λ/n)³ and as low as 1.37(λ/n)³. Although the index contrast between PMMA and air is only 1.52, significant photon bandgaps are possible.

Referring to FIG. 4, an exemplary SPPC ladder cavity suspended by a mesh of supporting elements is disclosed. The ladder cavity of FIG. 4 is similar to the photonic waveguide of FIG. 2, except that a lattice of holes 412 can be formed in the polymer film 411. By way of example and not limitation, the holes 412 can be a one-dimensional array of rectangular or elliptical holes. Thus a ladder cavity 421 can be formed.

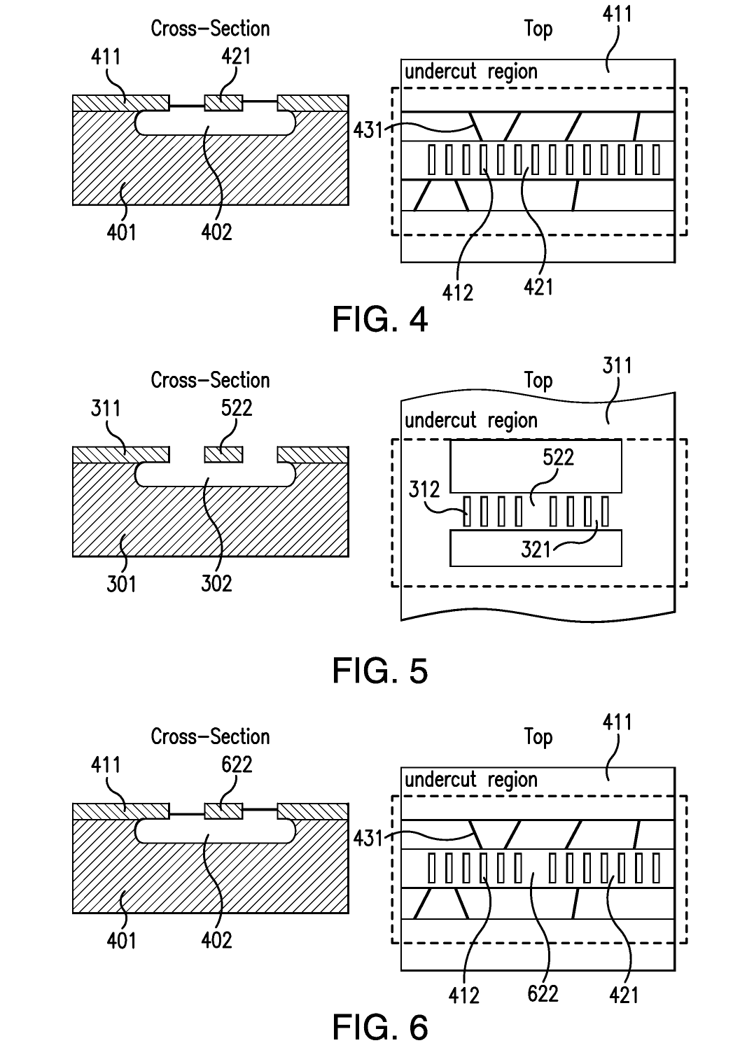

Referring to FIG. 5, an exemplary SPPC photonic crystal cavity in a 1D ladder cavity is disclosed. The 1D ladder cavity of FIG. 5 is similar to the ladder cavity of FIG. 3, except that a photonic crystal cavity 522 can be formed by a defect in the 1D lattice of holes 312. The defect can be the size of 1 missing hole. Thus, a photonic crystal cavity 522 can be formed within the ladder cavity 321.

Referring to FIG. 6, an exemplary SPPC photonic crystal cavity in a 1D ladder cavity supported by a mesh of supporting elements is disclosed. The 1D ladder cavity of FIG. 6 is similar to the ladder cavity of FIG. 4, except that a photonic crystal cavity 622 can be formed by a defect in the 1D lattice of holes 412. The defect can be the size of 1 missing hole. Thus, a photonic crystal cavity 622 can be formed within the ladder cavity 421.

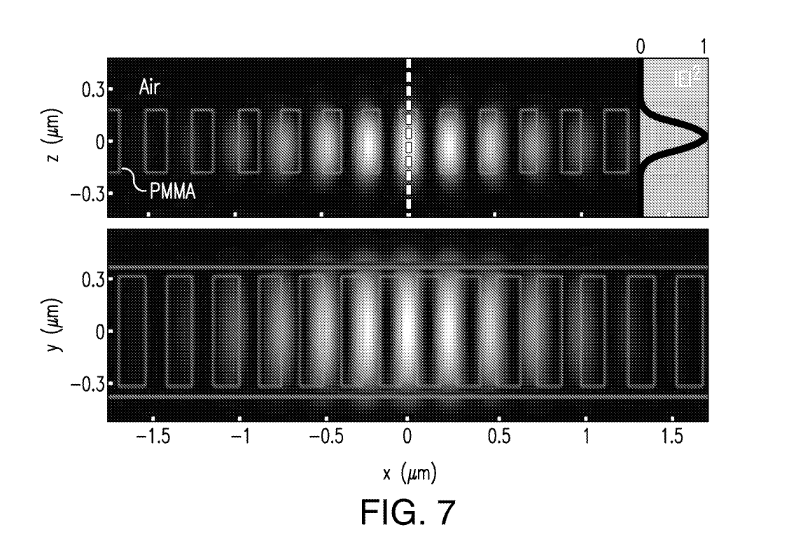

FIG. 7 shows the energy field distribution of simulated resonant modes in a ladder cavity at the normalized wavelength of twice the lattice spacing with a Q-factor of 107,500. The top image is a cross-section view. The bottom image is a top view.

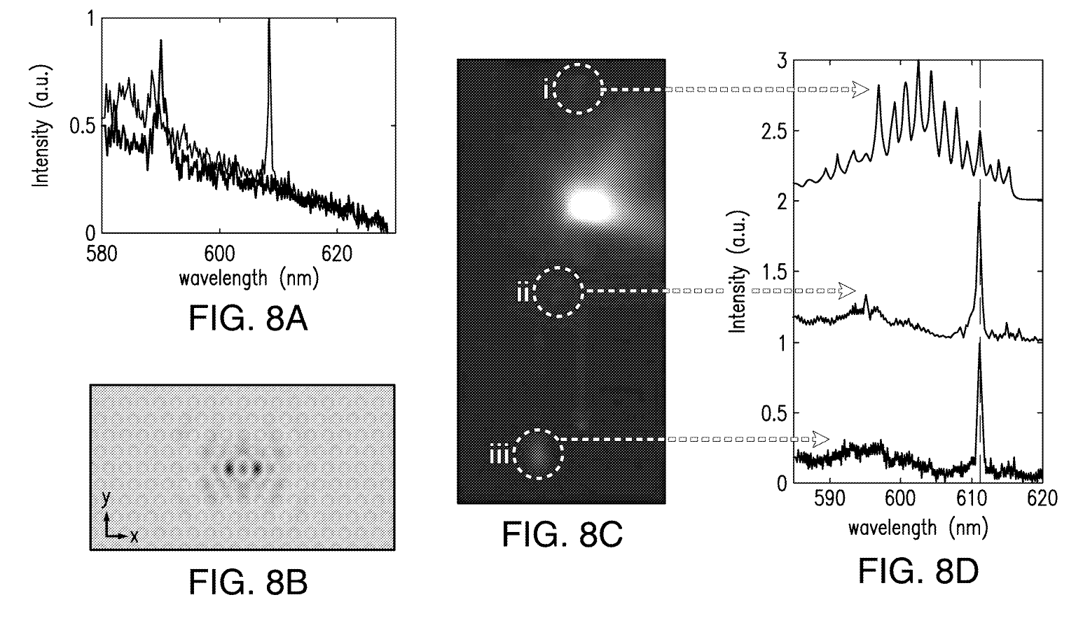

FIGS. 8A-D show experimental characterizations of 2D photonic crystal cavities and waveguides. FIG. 8A shows PL spectra from an L3 cavity, where red and blue lines correspond to perpendicular polarizations. FIG. 8B shows simulated mode distribution of the cavity in FIG. 8A. FIG. 8C shows transmissions of 2D photonic waveguides with different lengths. FIG. 8D shows the PL spectra from a resonator-waveguide coupled drop filter.

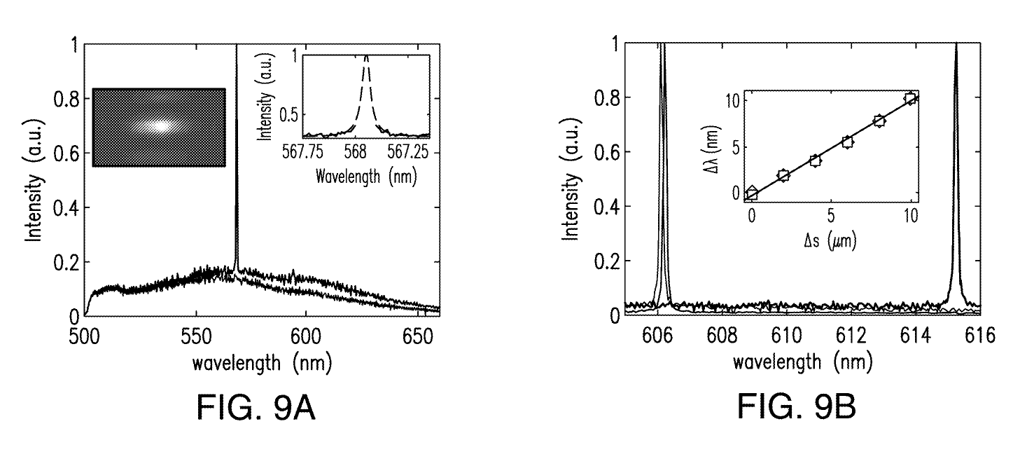

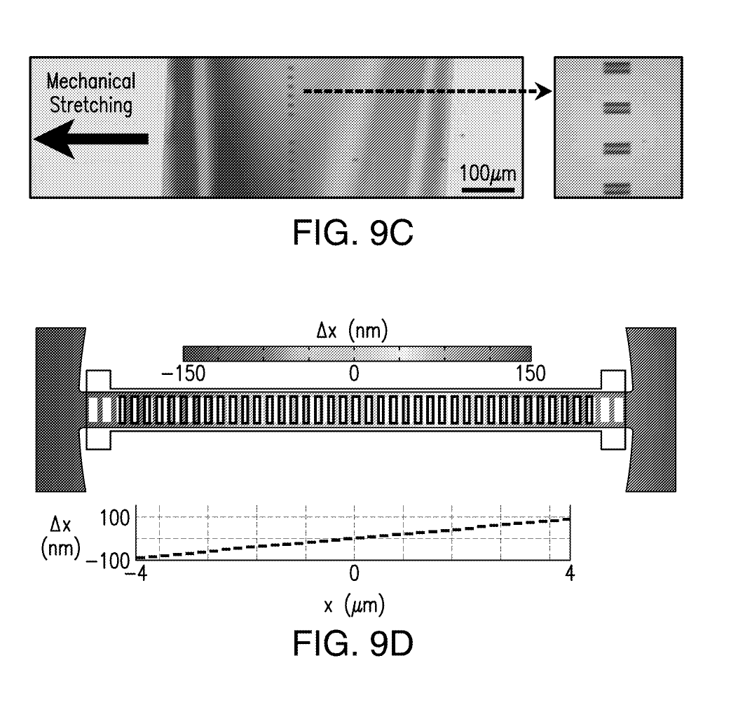

FIGS. 9A-B show images of the implementation of a 1D ladder cavity-based stretch sensor. FIG. 9A shows the characterization result of the 1D ladder cavity with red and blue lines depicting PL with perpendicular polarizations; the insets show the PL image (left) and the Lorentzian fit (right) of the cavity mode. FIG. 9B shows the spectra acquired from the ladder cavity with different stretching forces, where the green and red curves are the smallest distinguished displacement and the blue curve shows the maximum displacement. FIG. 9C is an optical microscope image of a ladder cavity displacement sensor according to some embodiments of the disclosed subject matter. A PMMA film with ladder cavities can be suspended on a mechanical carrier, which can be mounted on two piezo actuators to stretch the flexible ladder cavities. The device can include multiple ladder cavities for different optical waveguide detecting. An exemplary device used in connection with FIGS. 9A-D can have 12 ladder cavities. The ladder cavities have lengths of 10 μm with width of 1.5 μm. FIG. 9D shows the simulation result of a ladder cavity with an external stretching force.

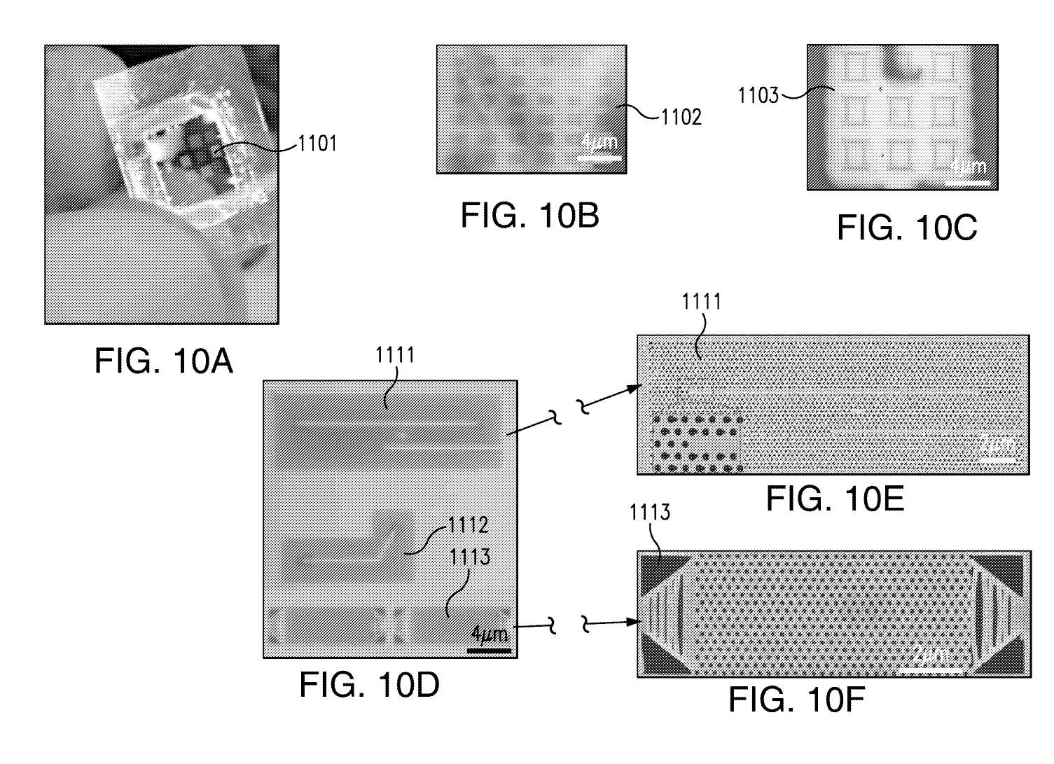

FIGS. 10A-F show images of various suspended polymer photonic crystal (SPPC) devices. FIG. 10A shows a photograph of 1 cm²-sized PMMA film with SPPC devices 1101 mounted on a polymer carrier substrate in accordance with some embodiments of the disclosed subject matter. FIGS. 10B-C are optical microscope images of SPPC devices 1102 transferred onto a fiber tissue and SPPC devices 1103 transferred onto a photo resist polymer substrate, respectively, after undercutting. The carrier substrate can be made of any conceivable material. FIG. 10D shows an optical microscope image of several SPPC devices, including an SPPC drop filter 1111, a 60 degree bend waveguide 1112, and a band-edge filter 1113. FIGS. 10E-F show scanning electron microscope images of an SPPC drop filter 1111 and band-edge filter 1113, respectively.

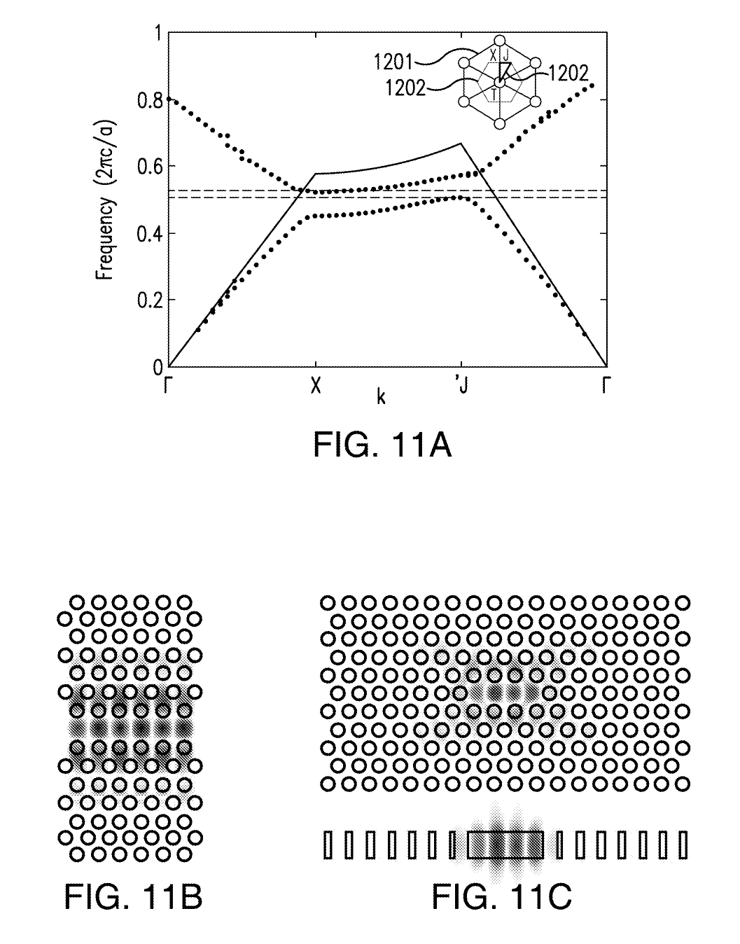

FIGS. 11A-C show simulations of hexagonal lattice SPPC devices where the radius of the holes is 0.3 times the lattice spacing and the thickness of the film is 1.3 times the lattice spacing. FIG. 11A shows a transverse electric-like (TE-like) mode band diagram for an SPPC with a bandgap between 0.487(2πc/a) and 0.503(2πc/a), where c is the speed of light in a vacuum and a is the lattice spacing. In such a system, there can be 3D light confinement by in-plane distributed Bragg reflection (DBR) and total internal reflection (TIR). The blue solid line shows the light line for air. The inset shows the reciprocal lattice 1201 (orange circles), the first Brillouin zone 1202 (blue), and the irreducible Brillouin zone 1203 (green) with high symmetry points. FIG. 11B shows the guided mode of an SPPC waveguide at

k=π/a, (4)

where k is the wave number. This indicates the well confinement of light in the wavelength scale. FIG. 11C shows the frequency of the confined and fundamental modes of an L3 cavity from a top view (top image) and a cross-section view (bottom image). The Q-factor of the resonant mode can be 3,000 and the mode volume can be 1.68(λ/n)³, where λ is the wavelength and n is the refractive index.

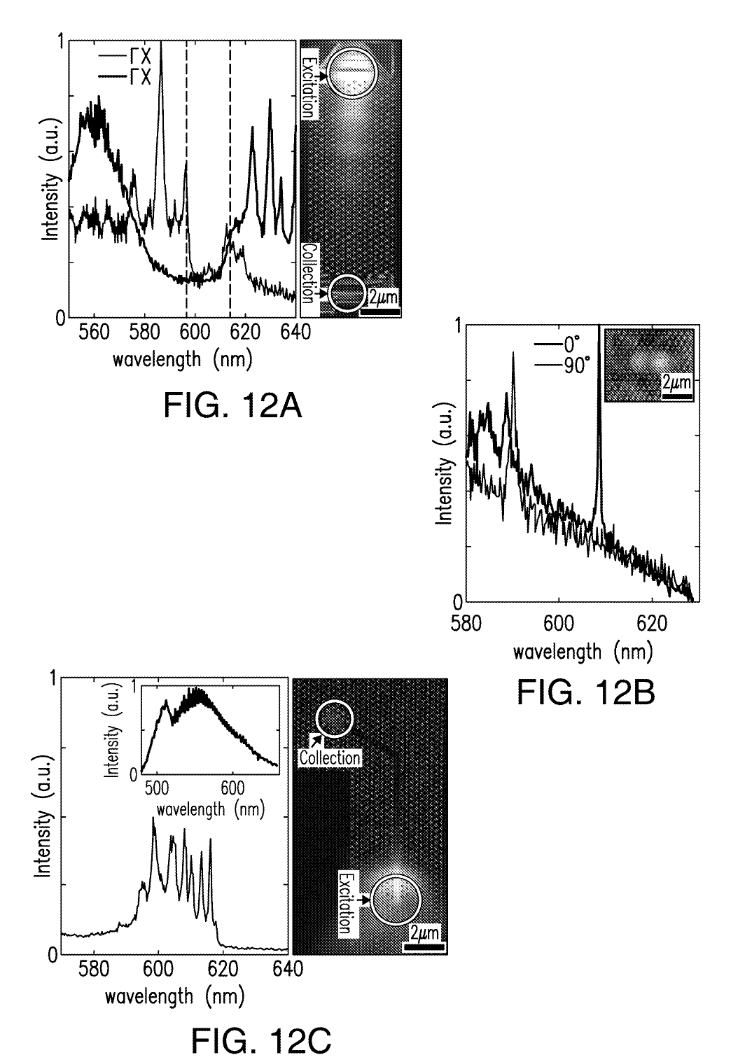

FIGS. 12A-C show experimental results of the PBG of certain SPPC devices, the resonance of an L3 cavity, and the transmission of a bend waveguide. FIG. 12A shows, on the left, transmission spectra of an SPPC band edge filter along ΓX and ΓJ directions. The region between the two dashed lines represents the in-plane complete bandgap in the spectral range of 597-615 nm. On the right, a PL image of the bandgap filter is superimposed with a scanning electron microscope image of the bandgap filter. FIG. 12B shows the PL spectra collected from an L3 cavity, which indicates sharp cavity resonance modes with perpendicular polarizations. The L3 cavity can have a fundamental mode at 611.3 nm, which can have a Q-factor of 2,300 when fit to a Lorentzian function. The inset shows the PL image of the fundamental cavity mode superimposed with the scanning electron microscope image of the cavity, which has two bright lobes at the terminals of the defect. FIG. 12C shows, on the left, the transmission spectra from an input vertical coupler (bottom) at one end of a 60 degree bend waveguide and an output vertical coupler (top) at the other end. The vertical couplers can be made by enlarged air holes at the ends of the waveguides. On the right, the PL image of the 60 degree bend waveguide is shown superimposed on the scanning electron microscope image of the 60 degree bend waveguide. There can be a bright spot at an output vertical coupler at one end of the 60 degree bend waveguide.

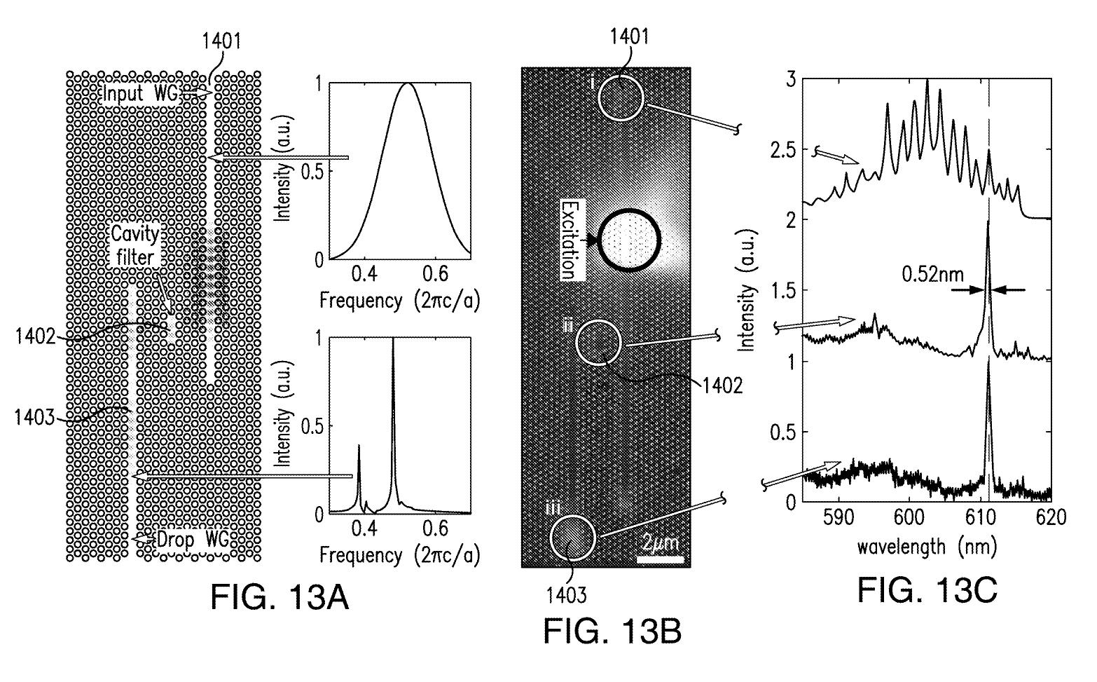

FIGS. 13A-C show a demonstration of an SPPC waveguide-coupled cavity drop filter. The drop filter can include two waveguides coupled via an L3 cavity. FIG. 13A shows a simulation of such a drop filter. A broadband electromagnetic radiation source can excite on the input waveguide 1401. Enlarged air holes can be designed at the ends of the waveguides 1401 and 1403 to act as vertical couplers. A high overlap between one of the input waveguide 1401 modes and the cavity 1402 mode can allow for efficient cavity-waveguide coupling. Photons from the cavity can 1402 leak back into the input waveguide 1401 and form a resonance with the input waveguide 1401, which can present a high peak in the cavity 1402 modes. Since the cavity 1402 can be narrower and within the modes of the waveguides 1401 and 1403, the cavity 1402 can couple to the drop waveguide 1403. A well-confined waveguide mode with narrow spectral width can be obtained in the drop waveguide 1403. Thus, the electromagnetic radiation can be filtered by the L3 cavity 1402. If the cavity 1402 is made active by the addition of electrically or optically controllable refractive index, the filtering by the cavity 1402 can be dynamic and provide control of the resonant wavelength for tuning, ultrafast modulation, or switching. By way of example and not limitation, the waveguides 1401 and 1403 and the cavity 1402 can be defined by defects in a lattice, as discussed above. By way of example and not limitation, the lattice can be a two-dimensional hexagonal array of holes, as discussed above. By way of example and not limitation, the cavity 1402 can be separated from each of the waveguides 1401 and 1403 by four rows of holes of the two-dimensional hexagonal array.

The insets show one possible broadband source of electromagnetic radiation (top) and the corresponding possible well-confined waveguide mode (bottom). FIG. 13B shows a PL image of a drop filter superimposed with a scanning electron microscope image of the drop filter. The PL generated on the input waveguide 1401 can transmit through the cavity 1402 and scatter out from a vertical coupler on the input waveguide 1401. FIG. 13C shows the spectra of light collected from a vertical coupler on waveguide 1401 (top), the cavity 1402 (center), and a vertical coupler on the drop waveguide 1403 (bottom). The peaks of the spectra from the cavity 1402 and the drop waveguide 1403 indicate sub-nanometer (about 0.52 nm) filtering of the cavity 1402.

FIGS. 14A-B show the energy density distribution of an L3 cavity (FIG. 14A) and an M3 cavity (FIG. 14B) according to some embodiments of the disclosed subject matter. The cavities can be defined by defects in a two-dimensional hexagonal array of holes in a polymer film, as described above. An M3 cavity can be formed by adding three linearly aligned holes into an L3 cavity. The holes of an M3 cavity can be of any shape, e.g., circular or elliptical. Also, the holes of an M3 cavity can have different spacing and radii than the holes of the surrounding lattice. The shape, size, and spacing of the holes of an M3 cavity can be adapted to tune the mode frequency of the narrow bandgap of the cavity and to increase the Q-factor of the cavity. Cavities can be fine-tuned by changing the hole positions and shapes near the photonic crystal defect region. A well known concept is to tune the cavity frequency into the frequency region of the photonic crystal bandgap. This can be done by changing the effective refractive index seen by the mode. Higher index can lead to lower frequency, and vice versa.

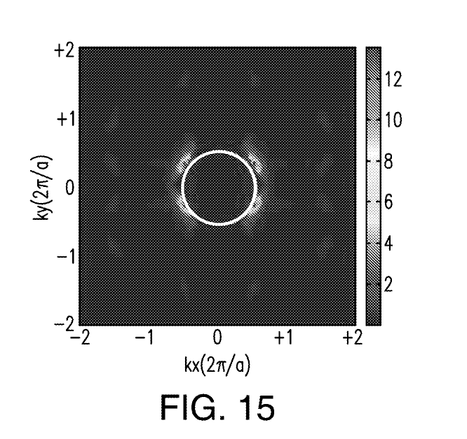

FIG. 15 shows the spatial Fourier Transform (FT) of the confined electric field for a resonant mode at the frequency of 0.5217 for a polymer photonic crystal L3 cavity according to some embodiments of the disclosed subject matter. The spatial FT is the k-space distribution in a plane-wave basis. Modes can be confined if the constituent plane waves are outside the light cone ω=ck, where ω is the electromagnetic mode frequency and c is the speed of light. In FIG. 15, the FT of the mode is located outside of the light line, showing vertical confinement of the mode due to the total internal reflection.

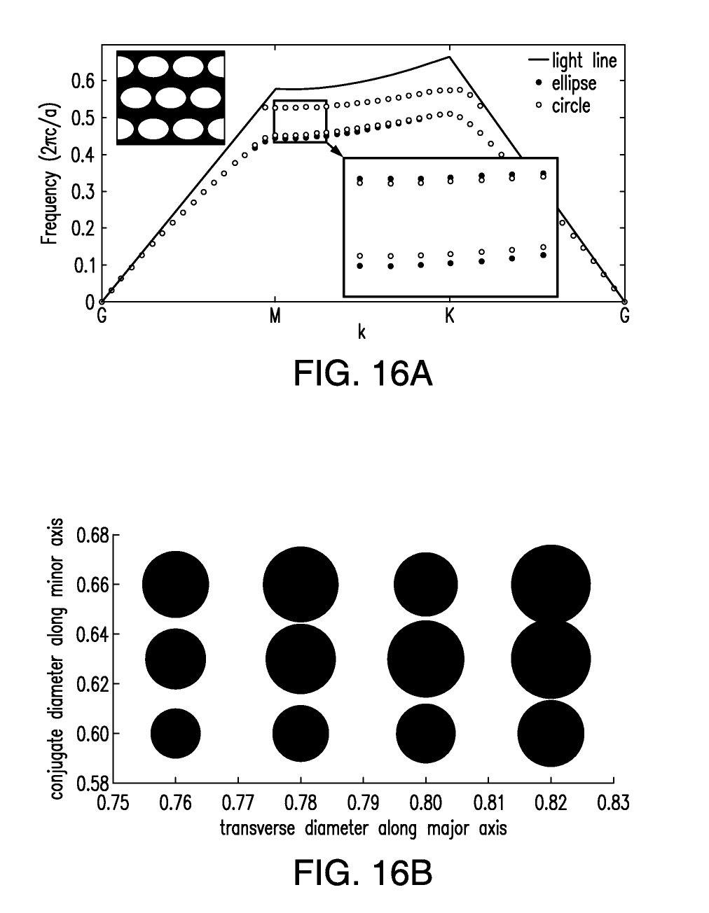

FIGS. 16-A-B show the comparison between elliptical photonic crystal PBG and related circular photonic crystal PBG (FIG. 16A) and PBG improvement of an elliptical photonic crystal according to some embodiments of the disclosed subject matter (FIG. 16B). The change in the hole geometry can enable tuning of the frequency of the photonic crystal bandgap in different directions. To enhance the Q-factor of the L3 cavity, all of its k-space components can be outside the light cone and inside the bandgap. This can be accomplished by tuning the frequency of the cavity mode, and one can also tune the photonic band structure to provide enhanced confinement into the relevant crystal directions, i.e., the primary directions in which the field is directed. In FIGS. 16A-B, the photonic crystals with elliptical holes display a high gap-midgap ratio of the PBGs, which can enable well-confined defect modes in-plane.

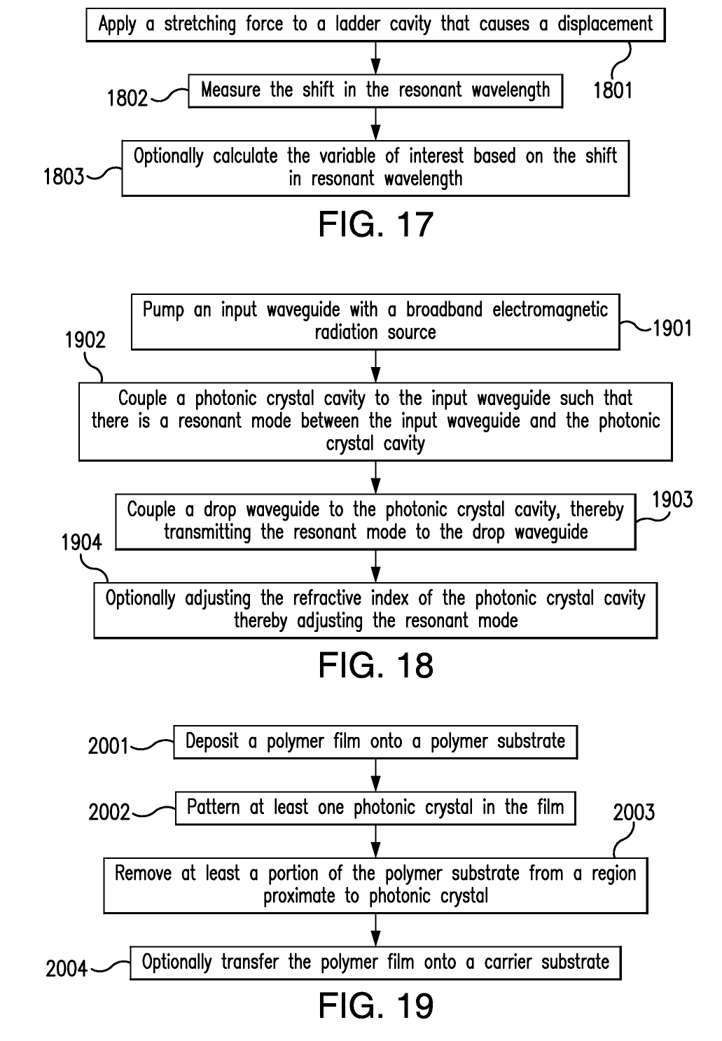

Referring to FIG. 17, an exemplary method for sensing using a polymer photonic crystal ladder cavity is disclosed. The photonic crystal ladder cavity can have a resonant wavelength. A stretching force can be applied to the ladder cavity to cause a displacement (1801). The displacement can result in a shift in the resonant wavelength. The shift in the resonant wavelength can be very accurately measured (1802). The minimum shift in resonant wavelength Δλₘᵢₙ that can be detected can be limited by the Q-factor of the cavity and the number of photons collected per second, e.g.,

Δλₘᵢₙ=(λ₀/Q)/\sqrt{N}, (5)

where λ₀ is the resonant wavelength of the unloaded cavity and N is the number of photons collected in one second. By way of example and not limitation, shifts in the resonant wavelength as small as 0.1 nm can be detected in a PMMA ladder cavity with original resonant wavelength of 606.1 nm and Q-factor of 6,100. Then, the shift in the resonant wavelength can be used to calculate a variable of interest (1803).

By way of example and not limitation, the shift in resonant wavelength can be used to calculate displacement at the nanometer scale. The displacement ΔL can be equal to L(Δλ/λ₀) where L is the length of the ladder cavity. By way of example and not limitation, in a PMMA ladder cavity with original resonant wavelength of 606.1 nm and Q-factor of 6,100, a shift in resonant wavelength of 0.1 nm can correspond to a 0.05 nm displacement of the lattice spacing. By way of example and not limitation, the ladder cavity can have 30 periods, which can indicates a 50 nm total displacement of the PMMA film, as calculated from the software COMSOL Multiphysics, which is commercially available software. By way of example and not limitation, the ladder cavity can be a 400 nm thick PMMA film where initial lattice spacing a can be 286 nm, beam width w₀ can be 2.8a, initial hole width can be 0.52a, and hole height can be 0.84w₀. The holes in the ladder cavity can have parabolically decreasing lattice spacing over 5 periods down to 0.9a at the center of the cavity. The Q-factor can be 107,500 at the normalized wavelength λ of 2a and a mode volume of 1.37(λ/n)³. The device is suspended on an air-gap of 320 μm. The film can be doped with organic dye (e.g. Coumarin 6, 5% by weight) and excited with a continuous-wave 405 nm diode laser to create internal PL around 480 to 650 nm. The resonance mode can be at the wavelength 568.1 nm, which can have a quality factor of 13,134. Finite element simulations can also be performed using COMSOL Multiphysics, which is commercially available software, to estimate the shift in wavelength that corresponds to a given displacement. See FIG. 9 for (d) simulation results of a ladder cavity with an external stretching force and (b) measured sensing results of ladder cavities.

By way of example, the shift in resonant wavelength can be used to calculate the stretching force. The stretching force F can be calculated by

F=EA(Δλ/λ₀), (6)

where E is the Young's modulus of the film and A is the cross-sectional area of the ladder.

In some embodiments, biochemical compounds, such as antibodies or single-stranded DNA can be incorporated into the ladder cavity. These compounds can then selectively bind to other compounds and cause a swelling of the polymer cavity, which results in a detectable resonance frequency change, as described below. The ladder cavity can be soaked in a solution, such as toluene, isopropyl alcohol, etc., which can cause the biochemical compounds to expand. Any solutions that cause the biochemical compound to expand can be used. Such expansion can result in a stretching force being applied to the ladder cavity which can cause a displacement (1801). As discussed above, the displacement can result in a shift in resonant wavelength, which can be measured very accurately (1802) and can be used to calculate a variable of interest (1803).

By way of example and not limitation, this method can be used to calculate the concentration of alcohol in air. Alcohol can penetrate into the polymer, which is porous and used to fabricate the ladder cavity. The penetration of alcohol cause the expansion of the ladder cavity, and shift the resonant wavelength.

Referring to FIG. 18, an exemplary method for optical filtering using an SPPC waveguide-coupled cavity drop filter is disclosed. A broadband electromagnetic radiation source can pump an input waveguide (1901). A photonic crystal cavity can be coupled to the input waveguide such that there is a resonant mode between the input waveguide and the cavity (1902). A drop waveguide can be coupled to the cavity to thereby transmit the resonant mode to the drop waveguide (1903). Optionally, the refractive index of the photonic crystal cavity can be adjusted, thereby adjusting the resonant mode (1904). By way of example and not limitation, one embodiment of an SPPC system that practices this method is discussed above in connection with FIG. 13.

Referring to FIG. 19, an exemplary method for fabricating SPPC devices is disclosed. A polymer film can be deposited onto a polymer substrate (2001). At least one photonic crystal device can be defined in the polymer film (2002). By way of example and not limitation, patterning a photonic crystal into the film can be accomplished by electron beam lithography, optical beam lithography, or nanoprinting. By way of example and not limitation, the polymer film can include a mesh of support elements therein, and a photonic crystal can be patterned into the film by exposing channels that surround the crystal so that only the mesh of support elements remains in the channels.

At least a portion of the substrate can then be removed from a region proximate to the photonic crystal (2003). By way of example and not limitation, the methods discussed above can be used. By way of example and not limitation, a trench can be formed underneath the photonic crystal by a chemical etch, e.g., a hydrofluoric acid etch to remove at least a portion of a glass substrate. By way of example and not limitation, a trench can be formed by dissolving at least a portion of a PVA substrate underneath the photonic crystal. By way of example and not limitation, if the photonic crystal is formed by a defect in a 2D hexagonal lattice of holes, the portion of the substrate that is underneath the photonic crystal and lattice can be removed.

By way of example and not limitation, the substrate can be a layer of PVA, and the entire layer can be removed by immersing the entire structure in water, which can dissolve the entire PVA layer. The polymer film can then float to the surface of the water. Then the polymer film can be transferred onto a carrier substrate (2004). By way of example and not limitation, the carrier substrate can have a trench, and the photonic crystal can be suspended above that trench. By way of example and not limitation, the trench can be at least the size of the photonic crystal. By way of example and not limitation, the trench can be at least the size of the photonic crystal and a surrounding lattice of holes.

We claim:

1. A photonic crystal cavity, comprising:
a substrate having a trench on at least one surface; and
a polymer film suspended above the trench thereby forming a gap between at least a portion of the polymer film and the substrate, the polymer film including a plurality of holes to thereby form at least one optical cavity, the plurality of holes having a lattice spacing, each of the plurality of holes having a radius,
wherein the radius and the lattice spacing of the plurality of holes are adapted to increase a gap-midgap ratio.

2. The photonic crystal cavity of claim 1, wherein the polymer film comprises a film having a periodic two-dimensional hexagonal array of holes having one or more defects, and the at least one optical cavity is defined by the one or more defects.

3. The photonic crystal cavity of claim 2, wherein the radius comprises three-tenths of the lattice spacing, and wherein the polymer film comprises a film having a thickness of 1.3 times the lattice spacing.

4. The photonic crystal cavity of claim 2, wherein the radius comprises 0.36 times the lattice spacing, and wherein the polymer film comprises a film having a thickness 1.5 times the lattice spacing.

5. The photonic crystal cavity of claim 2, wherein the at least one optical cavity comprises a defect in the periodic two-dimensional hexagonal array, the defect having a size of three linearly aligned missing holes in the two-dimensional hexagonal array.

6. The photonic crystal cavity of claim 5, wherein radius and lattice spacing between six of the plurality of holes that are adjacent to the defect are adapted to attenuate a vertical radiation loss.

7. The photonic crystal of claim 5, wherein the defect further includes additional holes, each having a radius and spacing therebetween, wherein the shape, spacing, and radius of the additional holes are adapted to enhance a Q-factor.

8. The photonic crystal of claim 7, wherein the additional holes comprise a linear arrangement of three holes, including a first end hole, a middle hole, and a second end hole.

9. The photonic crystal cavity of claim 1, wherein the holes are patterned in a periodic one-dimensional array of rectangular holes, and wherein the optical cavity comprises a ladder cavity.

10. The photonic crystal cavity of claim 1, wherein the polymer film comprises 400 nm thick poly(methyl methacrylate).

11. A method for fabricating a suspended polymer photonic crystal, comprising:
depositing a polymer film onto a polymer substrate;
patterning at least one photonic crystal in the film;
removing at least a portion of the polymer substrate from a region proximate to the at least one photonic crystal; and
transferring the polymer film onto a carrier substrate.

12. The method of claim 11, wherein the polymer substrate comprises a polyvinyl alcohol (PVA) layer, and wherein removing at least a portion of the polymer substrate from a region proximate to the at least one photonic crystal comprises dissolving the PVA layer in water.

13. The method of claim 11, wherein patterning at least one photonic crystal in the film comprises defining a photonic crystal pattern by one of electron beam lithography, optical beam lithography, and nanoprinting.

14. The method of claim 11, wherein the polymer film has a mesh of supporting elements therein, and wherein patterning at least one photonic crystal in the film comprises exposing channels that surround the at least one photonic crystal so that only the mesh remains in the channels.

15. A method for sensing using a polymer photonic crystal ladder cavity suspended in air and having a resonant wavelength, comprising:
applying a stretching force to the ladder cavity that causes a displacement; and
measuring the shift in the resonant wavelength due to the displacement.

16. The method of claim 15, further comprising calculating the displacement based on the shift in the resonant wavelength.

17. The method of claim 15, further comprising calculating the stretching force based on the shift in the resonant wavelength.

18. The method of claim 15, wherein applying a stretching force to the ladder cavity that causes a displacement comprises:
incorporating biochemical compounds into the ladder cavity; and
soaking the ladder cavity in a solution thereby causing the biochemical compounds to expand.
